(19) United States
(12) Patent Application Publication
(10) Pub. No.: US 2001/0014508 A1
(43) Pub. Date: Aug. 16, 2001

(54) METHOD FOR PREVENTING JUNCTION LEAKAGE OF BORDERLESS CONTACT

(76) Inventors: TONY LIN, KAOHSIUNG HSIEN (TW); JIH-WEN CHOU, HSINCHU (TW)

Correspondence Address: J.C. Patents, Inc., 1340 Reynolds Avenue, Suite 114, Irvine, CA, 92614, US

(21) Appl. No.: 09/207,169

(22) Filed: Dec. 7, 1998

(51) Int. Cl. H01L 21/336

(52) U.S. Cl. 438/302; 438/303; 438/305; 438/306; 438/307

(57) ABSTRACT

A method for forming borderless contact capable of reducing junction leakage current by forming a deep junction in the source/drain region nearest the borderless contact to eliminate most of the leakage current. The method includes the steps of first forming a shallow trench isolation structure for isolating devices in a semiconductor substrate. In the subsequent step, an ion implantation is carried out implanting ions at a small tilt angle to form source/drain regions such that source/drain region nearest to the shallow trench isolation structure has a deep junction. Finally, a borderless opening is formed above the source/drain region and the shallow trench isolation structure, and then conductive material is deposited into the borderless opening to form the borderless contact.

### BACKGROUND OF THE INVENTION

1. Field of Invention

The present invention relates to a method for preventing junction leakage of borderless contact. More particularly, the present invention relates to a method for manufacturing borderless contact capable of preventing junction leakage above a shallow trench isolation structure that has a recess region.

2. Description of Related Art

According to conventional design rules for patterning out a contact window in an inter-layer dielectric (ILD) layer, some border areas must be reserved around the periphery of a contact window. Hence, even when contact window misalignment occurs, unwanted leakage current is not produced.

As the level of device integration in semiconductor chip increases, nowadays devices having a line width smaller than 0.25μm are quite common. To reduce area occupation by devices, conventional contact having a border region is gradually replaced by borderless contact.

However, should misalignment of pattern occur while the borderless contact opening is formed in a substrate and that the upper portion of the shallow trench isolation (STI) structure has a recess cavity, a leakage current may be generated in the neighborhood junction between the subsequently formed contact and the substrate.

FIGS. 1A through 1D are cross-sectional views showing the progression of manufacturing steps in producing a borderless contact according to the conventional method. First, as shown in FIG. 1A, a device isolation structure 101 is formed over a substrate 100. The device isolation structure 101, for example, can be a shallow trench isolation structure, and is used for bounding the active device region. Thereafter, a gate structure 102 is formed over the substrate 100, and then source/drain regions 108 are formed in the substrate 100 on each side of the gate structure. The gate structure 102 composes of a gate oxide layer 104 and a gate conductive layer 106. Next, spacers 110 are formed on the sidewalls of the gate structure 102. The source/drain regions 108 have a lightly doped drain (LDD) structure. The LDD structure is formed by carrying out a first ion implantation to form a lightly doped source/drain region using the gate structure 102 as a mask. Then, a second ion implantation is carried out to form a heavily doped source/drain region using the spacers 110 as masks.

The shallow isolation structure 101 as shown in FIG. 1A may end up with a structure as shown in FIG. 1B. In other words, the upper surface of the shallow trench isolation structure 110 is at a level lower than the source/drain region 108 of the device. If that is the case, then a heavy leakage current may be generated in the subsequently formed borderless contact.

Next, as shown in FIG. 1C, a silicon nitride layer 112 acting as an etching stop layer is subsequently formed over the substrate 100. Thereafter, an oxide layer 114 is deposited over the silicon nitride layer 112 to form an inter-layer dielectric layer (ILD).

Thereafter, as shown in FIG. 1D, a chemical-mechanical polishing (CMP) method is used to planarize the oxide layer 114. Hence, a borderless contact opening 116 is formed. Finally, conductive material is deposited to fill the contact opening 116 to form a borderless contact 118.

Since the upper surface of the shallow trench isolation structure 101 is at a level lower than the source/drain region 108, the borderless contact 118 has a low contact structure 120. Because junction depth of the source/drain region 108 is shallow, leakage current large enough to affect device's operating characteristic may flow in the contact structure 120.

In light of the foregoing, there is a need to provide a method for preventing junction leakage in borderless contact.

### SUMMARY OF THE INVENTION

Accordingly, the present invention is to provide a method for forming borderless contact capable of reducing junction leakage current. The method involves carrying out an ion implantation at a small tilt angle when the source/drain region is fabricated, thereby changing the junction structure in the source/drain region and eliminating most of the leakage current.

To achieve these and other advantages and in accordance with the purpose of the invention, as embodied and broadly described herein, the invention provides a method for forming borderless contact capable of reducing junction leakage current. The method includes the steps of first forming a shallow trench isolation structure for isolating devices in a semiconductor substrate, and then forming a gate structure above the substrate. Spacers are formed on the sidewalls of the gate structure. In the subsequent step, an ion implantation is carried out implanting ions at a small tilt angle to form source/drain regions such that source/drain region next to the shallow trench isolation structure has a deep junction. Thereafter, an inter-layer dielectric (ILD) layer is formed over the semiconductor substrate, and then the ILD is planarized. Finally, a borderless opening is formed above the source/drain region and the shallow trench isolation structure, and then conductive material is deposited into the borderless opening to form the borderless contact.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are cross-sectional views showing the progression of manufacturing steps in producing a borderless contact according to the conventional method; and

FIGS. 2A through 2C are cross-sectional views showing the progression of manufacturing steps in producing a borderless contact capable of reducing junction leakage current according to one preferred embodiment of this invention.

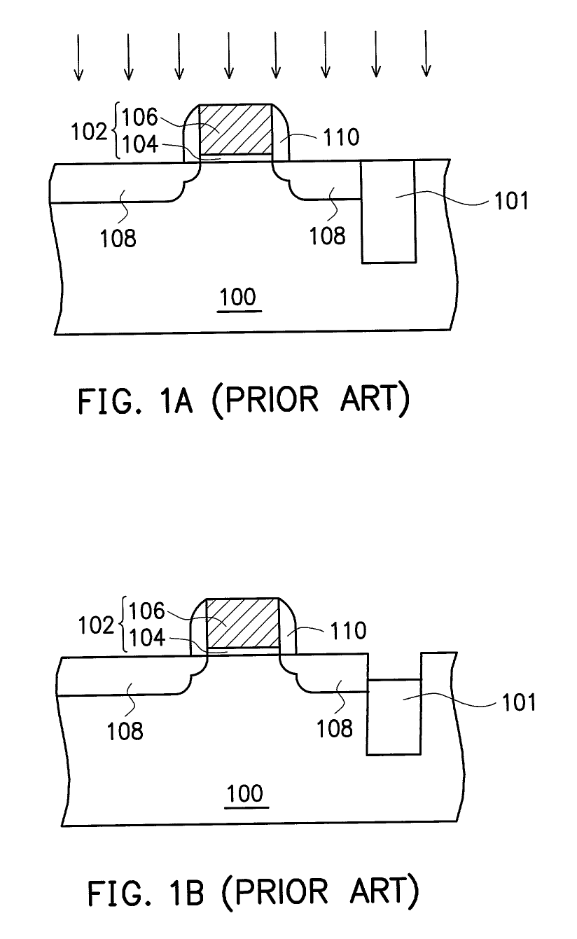

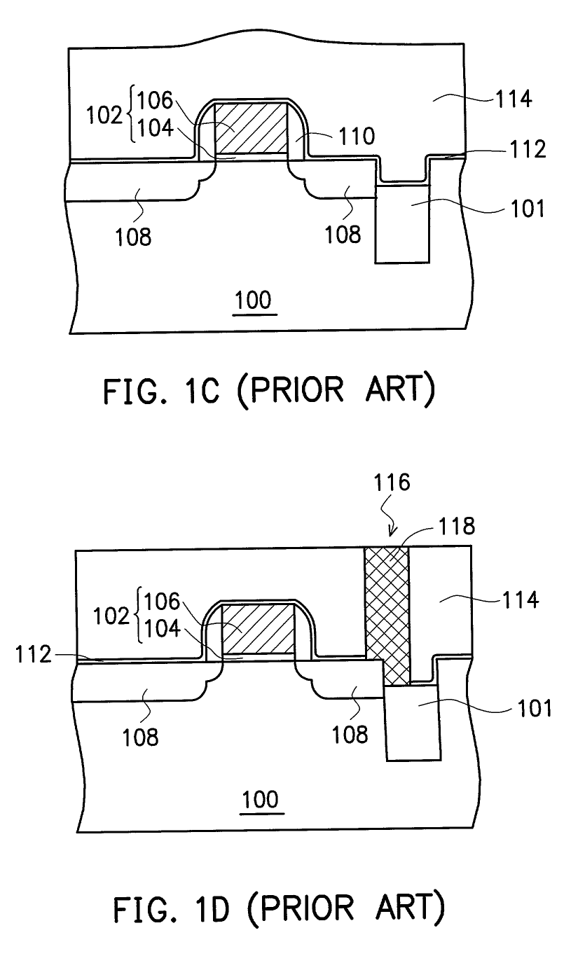

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

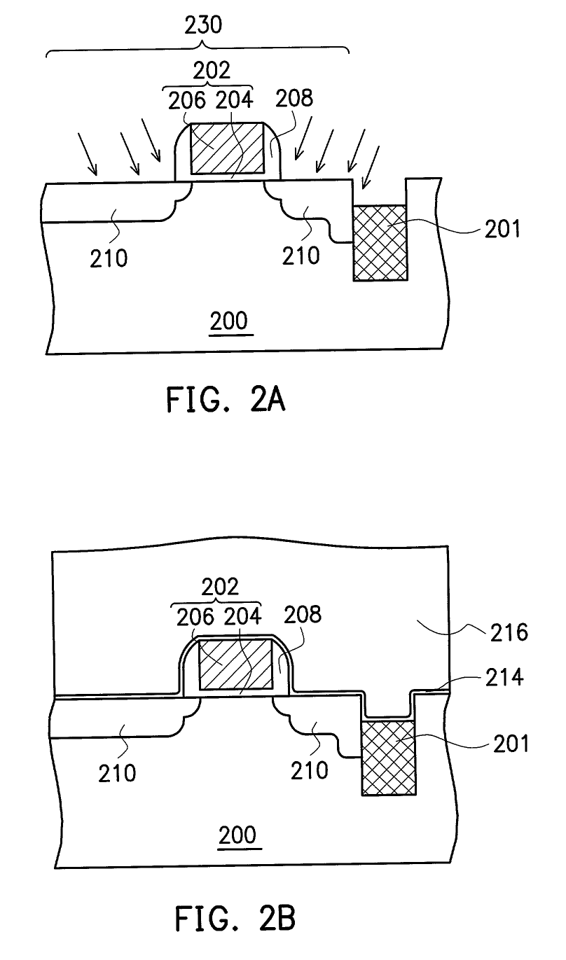

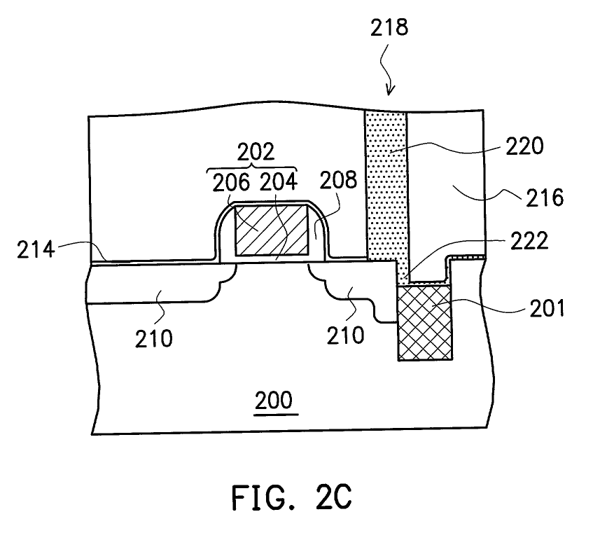

FIGS. 2A through 2C are cross-sectional views showing the progression of manufacturing steps in producing a borderless contact capable of reducing junction leakage current according to one preferred embodiment of this invention. As shown in FIG. 2A, a device isolation structure 201, for example, a shallow trench isolation structure is formed in a substrate 200. The device isolation structure 201 is used for marking out a device region 230. Thereafter, a gate structure 202 is formed over the substrate 200 in the device region 230. The gate structure 202 is composed of a gate oxide layer 204 and a gate conductive layer 206.

Sidewall spacers 208 are formed on each side of the gate structure 202. In the subsequent step, an ion implantation is carried out implanting ions at a small tilt angle as shown in the figure, thereby forming source/drain regions 210 in the substrate 200. If the upper surface of the shallow trench isolation structure 201 is at a level lower than the substrate surface, then the source/drain region next to the isolation structure 201 will have a deeper junction 212.

As shown in FIG. 2B, a silicon nitride layer 214 is formed over the substrate 200, the gate structure 202 and the shallow trench isolation structure 201. The silicon nitride layer 214 serves as an etching stop layer in subsequent etching operation. Then, an oxide layer 216 is deposited over the silicon nitride layer 214 to from an inter-layer dielectric layer.

Thereafter, as shown in FIG. 2C, a chemical-mechanical polishing (CMP) is applied to planarize the oxide layer 216, and then forming a borderless contact opening 218 above the source/drain region 210 and the shallow trench isolation structure 201. Finally, conductive material is deposited into the opening 218 to form a borderless contact 220.

Although the borderless contact 220 has a low contact structure 222, implanting ions at a tilt angle into the substrate 200 is able to form a deep junction 212 in the source/drain region 210 nearest to the shallow trench isolation structure 201. Hence, junction distance between the borderless contact 220 and the source/drain region 210 can be maintained, and the recess cavity above the shallow trench isolation structure will not lead to the production of a leakage current.

In summary, the characteristic of this invention includes implanting ions at a small tilt angle with respect to the substrate so that the source/drain region nearest the shallow trench isolation structure has a deep junction. Consequently, when a borderless contact is formed above the recess region of the shallow trench isolation structure, leakage current is greatly reduced due to the presence of a deep junction in the source/drain region. Therefore, the functional characteristics of a device are greatly improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing borderless contact capable of reducing junction leakage current, comprising the steps of:
providing a semiconductor substrate;
forming a shallow trench isolation structure for isolating out a device region;
forming a gate structure above the device region of the semiconductor substrate;
forming sidewall spacers on each side of the gate structure;
implanting ions at a tilt angle into the substrate to form a source/drain region;
forming an inter-layer dielectric layer over the substrate;
planarizing the inter-layer dielectric layer;
forming a borderless contact opening above the source/drain region and the shallow trench isolation structure; and
depositing conductive material into the borderless contact opening to form a borderless contact.

2. The method of claim 1, wherein the gate structure is further composed of a gate oxide layer and a gate conductive layer.

3. The method of claim 1, wherein the source/drain region nearest the shallow trench isolation structure has a deep junction.

4. The method of claim 1, wherein the step of planarizing the inter-layer dielectric layer includes using a chemical-mechanical polishing method.

5. The method of claim 1, wherein the upper surface of the shallow trench isolation structure is at a level lower than the upper surface of the source/drain region.

6. The method of claim 1, wherein the borderless contact has a low contact structure above the shallow trench isolation structure.

7. The method of claim 1, wherein after the step of implanting ions at a tilt angle to form the source/drain region, further includes forming a silicon nitride layer over the substrate.

8. A method of manufacturing borderless contact capable of reducing junction leakage current, comprising the steps of:
providing a semiconductor substrate;
forming a shallow trench isolation structure for isolating out a device region;
forming a gate structure above the device region of the semiconductor substrate;
forming sidewall spacers on each side of the gate structure;
implanting ions at a tilt angle into the substrate to form source/drain regions such that the source/drain region nearest the shallow trench structure has a deep junction;
forming a silicon nitride layer over the substrate;
forming an inter-layer dielectric layer over the silicon nitride layer;
planarizing the inter-layer dielectric layer;
forming a borderless contact opening above the source/drain region and the shallow trench isolation structure; and
depositing conductive material into the borderless contact opening to form a borderless contact.
